(19) United States
(12) Patent Application Publication
(10) Pub. No.: US 2006/0045158 A1
(43) Pub. Date: Mar. 2, 2006

(54) Stack-type Wavelength-tunable Laser Source

(76) Inventor: Chian Chiu Li, San Jose, CA (US)

Correspondence Address: CHIAN CHIU LI, 1847 BRISTOL BAY COMMON, SAN JOSE, CA, 95131-3802, US

(21) Appl. No.: 11/162,083

(22) Filed: Aug. 29, 2005

Related U.S. Application Data
(60) Provisional application No. 60/605,634, filed on Aug. 30, 2004.

(51) Int. Cl. H01S 5/00

(52) U.S. Cl. 372/50.12; 372/50.121; 372/20

(57) ABSTRACT

A widely wavelength-tunable laser source is provided using stacked tunable diode laser arrays which have different working wavelengths. Top surfaces of the laser arrays are disposed opposite and proximate. A coupling element employs an actuator to couple a beam from the arrays to an output waveguide. The laser source combines wavelength-tuning ranges of the arrays. The laser source also provides a backup scheme when the arrays have the same structure.

### CROSS REFERENCE TO RELATED APPLICATION

This application claims the benefit under 35 U.S.C. Sec. 119 of provisional patent application Ser. No. 60/605,634, filed Aug. 30, 2004.

### BACKGROUND

1. Field of Invention

This invention relates to semiconductor lasers, and particularly to stack-type semiconductor laser devices.

2. Description of Prior Art

In fiberoptic telecommunication, a wavelength-tunable light source is often desired. One scheme for such a purpose involves a distributed feedback (DFB) laser array. The array contains a series of DFB diode lasers built on a common substrate. Each laser emits a beam at a specific wavelength and is thermally tuned within a narrow wavelength range. The beams are coupled into an output waveguide by adjusting an actuator respectively. The array combines each individual wavelength-tuning range of the DFB lasers such that it becomes a widely tunable laser source. This method provides a relatively simple tunable light source solution. However, it is difficult to expand the tuning range further, since the available wavelength is limited within a range determined by the array's substrate, the diode growth process, and the materials which fit the substrate and process.

### OBJECTS AND ADVANTAGES

Accordingly, several main objects and advantages of the present invention are:
a). to provide an improved tunable semiconductor laser source;
b). to provide such a laser source which stacks diode laser arrays together proximately;
c) to provide such a laser source which employs an actuator to drive a coupling element for coupling a beam from the arrays to a waveguide;
d). to provide such a laser source which has a wider wavelength-tuning range than the current tunable laser array; and
d). to provide such a laser source which has improved reliability by having a backup solution.

Further objects and advantages will become apparent from a consideration of the drawings and ensuing description.

### SUMMARY

In accordance with the present invention, two diode laser arrays are stacked together to generate a stack-type widely tunable laser source. An adjustable coupling element is used to couple a beam from the arrays into an output waveguide. The laser source combines tuning ranges of the arrays and thus has a wider tuning range than the current single diode laser array. In another embodiment, the arrays are similar and one works as a backup to improve the reliability of the laser source.

ABBREVIATIONS

| | |
|---|---|
| DBR | Distributed Bragg Reflector |
| DFB | Distributed Feedback |
| LED | Light-emitting Diode |
| MEMS | Micro-electro-mechanical-system |
| VCSEL | Vertical Cavity Surface Emitting Laser |

### DRAWING FIGURES

FIG. 1-A illustrates schematically a prior-art tunable laser source having a one-dimensional diode laser array and an adjustable mirror.

FIG. 1-B is a schematic cross-sectional view of a prior-art one-dimensional diode laser array.

FIG. 2-A is a schematic diagram of an embodiment having stacked diode lasers and an adjustable mirror.

FIGS. 2-B to 2-D are schematic cross-sectional views of embodiments of stacked diode lasers.

FIG. 2-E is a schematic cross-sectional view of stacked one-dimensional diode laser arrays.

FIG. 2-F is a schematic cross-sectional view of an embodiment where a one-dimensional diode laser array and a two-dimensional vertical cavity surface emitting laser (VCSEL) array are stacked.

FIGS. 3-A to 3-C show schematically cross-sectional views of bonding structures of stacked diode lasers.

FIGS. 4-A and 4-B are schematic diagrams of embodiments having stacked diode lasers and a movable optical coupling mechanism.

REFERENCE NUMERALS IN DRAWINGS

| | | | |
|---|---|---|---|
| 10 | diode laser array | 12 | laser diode |
| 14 | lens system | 16 | reflector |
| 18 | lens system | 20 | optical fiber |
| 22 | diode laser | 24 | diode laser |
| 26 | active region | 28 | active region |
| 30 | laser diode | 32 | laser diode |
| 34 | diode laser | 36 | laser diode |
| 38 | diode laser array | 40 | laser diode |
| 42 | submount | 44 | diode laser |
| 46 | bonding material | 48 | diode laser |
| 50 | wire | 52 | submount |
| 54 | submount | 56 | diode laser |
| 58 | submount | 60 | base plate |
| 62 | diode laser | 64 | diode laser |
| 66 | bonding material | 68 | submount |
| 70 | bonding material | 72 | submount |
| 74 | laser diode | 76 | VCSEL array |
| 78 | lens system | 80 | optical system |
| 82 | optical system | 84 | beam |
| 86 | wire | 88 | fiber end |
| 90 | diode laser array | 92 | laser diode |
| 94 | beam | 96 | diode laser |

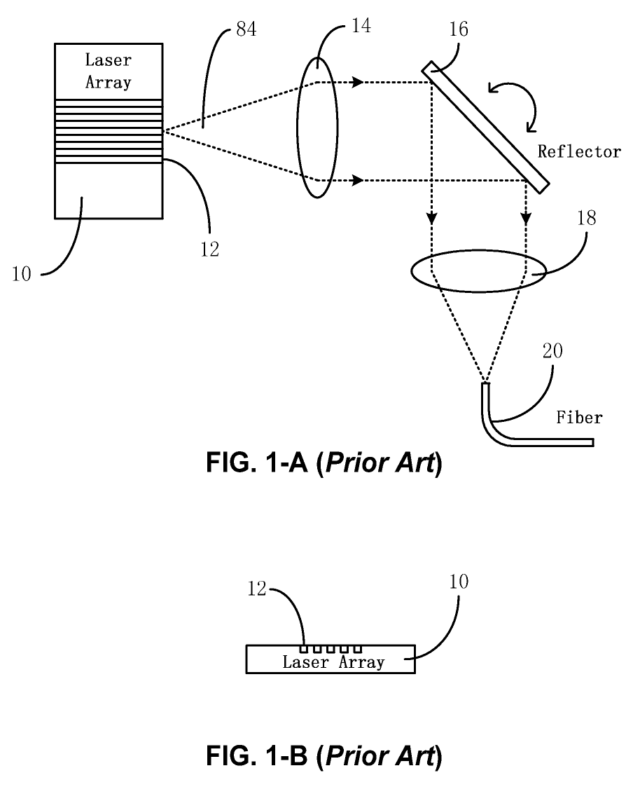

### DETAILED DESCRIPTION—FIGS. 1-A AND 1-B—PRIOR-ART

FIG. 1-A shows a schematic diagram of a prior-art wavelength-tunable light source. A one-dimensional edge-emitting diode laser array 10 contains several laser diodes 12. FIG. 1-B is a schematic cross-sectional view of array 10 in a direction perpendicular to the optical path. The lasers have a common substrate. Each diode covers a specific wavelength. Returning to FIG. 1-A, a beam 84 from a laser of array 10 is collimated by a lens system 14. The collimated beam is reflected by an adjustable mirror 16 and then coupled into an optical fiber 20 by a lens system 18. On the left hand side of lens system 14, the front facet of array 10 or the light emitting spots (not shown in FIG. 1-A) of the diodes are placed in its focal plane such that every beam from array 10 is collimated; on the right hand side of lens system 14, the location of mirror 16 coincides with the lens' focal point so that beams from the laser array are not only reflected by the mirror, but also converge at the mirror.

As a result of the configuration of FIG. 1-A, any beam from the array can be coupled into fiber 20 by moving and tilting mirror 16. When the array switches from one laser to another, two control systems are used. An alignment control system detects coupling efficiency between the beam and fiber 20, while a mirror control system tunes the position and location of the mirror. The alignment control system includes several optical sensors to monitor location of the beam. The mirror control system contains an actuator which is preferably of micro-electro-mechanical-system (MEMS) type due to its compact size and mass production ability.

In the prior art, the laser array employs either a one-dimensional edge-emitting diode laser array or a two-dimensional VCSEL array, both of which share one substrate. The single substrate, the diode fabrication process, and the materials suitable for the substrate and the process restrict the available output wavelength within a certain range.

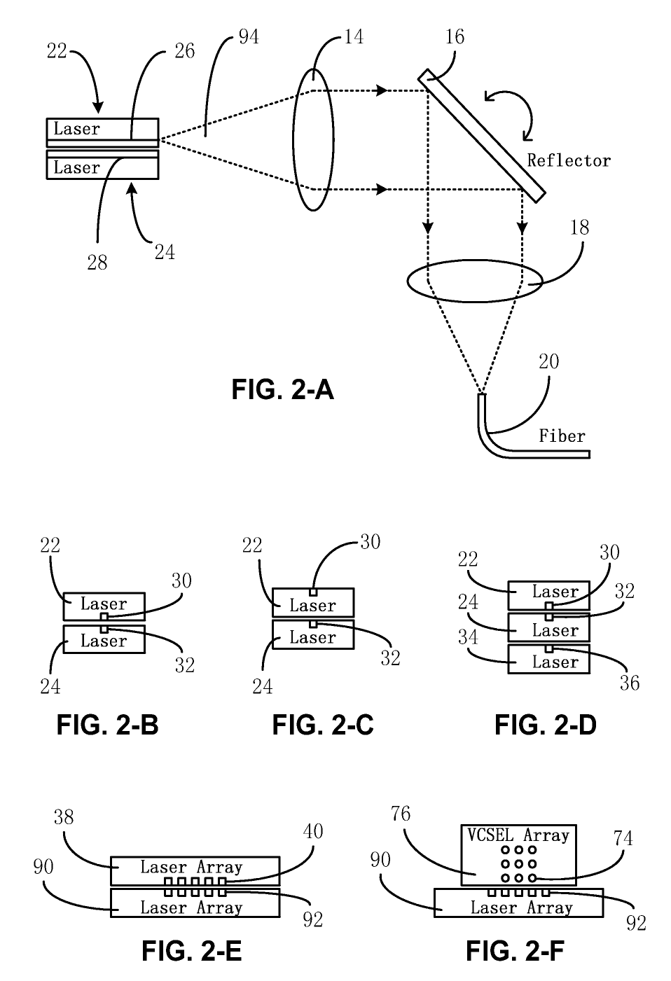

FIGS. 2-A-2-F—Laser Source Using Stacked Diode Lasers

FIG. 2-A shows schematically a diagram of a laser source using stacked diode lasers according to the invention. The setup of FIG. 2-A is similar to that of FIG. 1-A except laser array 10 is replaced by discrete diode lasers 22 and 24 which are in a stack-type configuration. Lasers 22 and 24 are of edge-emitting type and have active regions 26 and 28, respectively. An active region is where the light is generated. A beam 94 is emitted from a light emitting spot (not shown in FIG. 2-A) on the front facet of laser 22. The front facets of the lasers are disposed in the focal plane of lens system 14, and a beam from either diode is coupled into an output fiber 20 by adjusting mirror 16. Like beam 84 of FIG. 1-A, beam 94 is collimated by lens system 14, reflected by adjustable mirror 16, and coupled into fiber 20 by lens system 18. Since diode lasers 22 and 24 may be fabricated separately, they may have different structures and different output wavelengths. When the diodes are stacked, the stack-type laser source combines wavelength ranges of the lasers. Lasers 22 and 24 may also have the same structure such that one laser may work as a backup.

FIG. 2-B illustrates a schematic cross-sectional view of stacked lasers 22 and 24 in a direction perpendicular to the light propagation direction. Laser 22 and 24 contain laser diodes 30 and 32 respectively, which are typically atop a substrate and close to a top surface of the laser. The lasers are disposed such that their top surfaces are opposite and proximate.

The stack structure is not restricted to the type shown above and may possess a variety of variations in terms of materials, fabrication methods, and diode types. The structure may include a diode laser and a diode laser array, two diode laser arrays, or two arrays where one is edge-emitting type and the other is VCSEL type. FIGS. 2-C to 2-F illustrate schematically examples of some structures in a cross-sectional view perpendicular to the light propagation direction.

Referring to FIG. 2-C, laser 22's bottom surface is opposite laser 24's top surface. In such a configuration, a thin substrate of laser 22 is preferred, since it means a short distance between diodes 30 and 32 and a short separation between two light emitting spots (not shown in FIG. 2-C), which in turn results in a desirable short adjusting range of mirror 16.

In FIG. 2-D, three lasers 22, 24 and 34 are stacked in a direction perpendicular to the diodes' substrates, where lasers 22 and 24 have their top surfaces facing each other, and laser 34's top surface along with a diode 36 is opposite laser 24's bottom surface. The embodiment may provide a light source comprising three diode laser types.

In FIG. 2-E, 38 and 90 are one-dimensional edge-emitting diode laser arrays containing laser diodes 40 and 92. If arrays 38 and 90 are of tunable diode lasers having different working wavelengths, the resulting wavelength-tuning range of the stacked arrays will be larger than either single array. Therefore the stack-type laser arrays extend the tuning range provided by the current diode laser array. If arrays 38 and 90 are the same, each diode of one array will have a backup diode from the other array. Thus reliability issue is bettered. Since the embodiment of FIG. 2-E represents a two-dimensional diode laser array, it requires a more robust mirror control system than a one-dimensional array of FIG. 1-A.

As a ramification of FIG. 2-E, embodiment of FIG. 2-F consists of one-dimensional edge-emitting diode laser array 90 and a two-dimensional VCSEL array 76. The VCSEL array is disposed such that its substrate is perpendicular to array 90's substrate. As previously discussed referring to FIG. 2-A, the front facets or the light emitting spots of all diode lasers in the arrays should be in the focal plane of lens system 14. In another embodiment (not shown), array 90 is substituted by anther VCSEL array to create stacked VCSEL arrays.

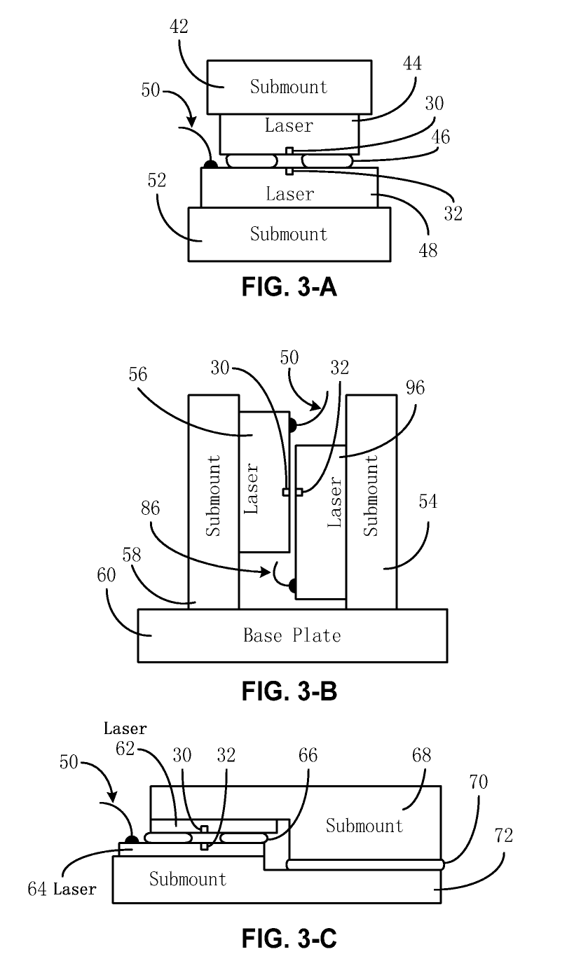

FIGS. 3-A-3-C—Bonding Stuctures of Stacked Lasers

FIG. 3-A shows schematically a cross-sectional view of stacked lasers according to the invention. Lasers 44 and 48, which have diodes 31 and 32, are mounted on submounts 42 and 52, respectively. The diodes are bonded together by a bonding material 46. A wire 50 is bonded onto laser 48 as an electrode. If material 46 have good electrical conductivity, wire 50 also serves as laser 44's electrode; otherwise, another electrode wire is needed for laser 44.

In FIG. 3-B, lasers 56 and 96 along with wires 50 and 86 are bonded to submounts 58 and 54, which are bonded onto a base plate 60. As discussed before, the closer diodes 30 and 32 are, the less demanding the mirror control system is required to be.

Another bonding embodiment is shown schematically in FIG. 3-C. Stacked lasers 62 and 64 are held together by three bonding regions. A bonding material 66 bonds together lasers 62 and 64, while a bonding material 70 bonds submounts 68 and 72. Submount 68 and 72 may be connected to heat sinks (not shown in FIG. 3-C) separately.

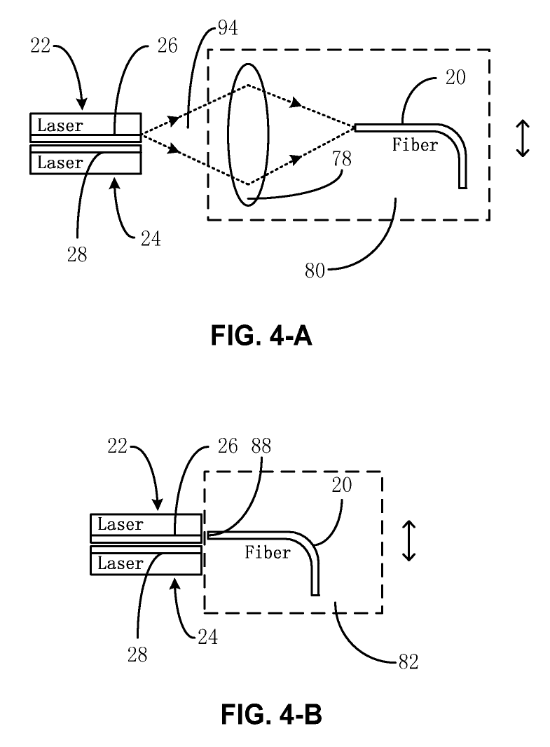

FIGS. 4-A And 4-B—Embodiments Using Direct Coupling Methods

FIG. 4-A illustrates schematically a diagram employing stacked lasers and a coupling mechanism according to the invention, where a lens system 78 couples beam 94 directly into fiber 20. Lens system 78 and fiber 20 forms an optical system 80 as symbolized with the broken line. System 80 is shifted by an actuator (not shown in FIG. 4-A) and controlled by an alignment control system (not shown in FIG. 4-A) so that it selectively feeds a beam from the stacked lasers into fiber 20.

In FIG. 4-B, the configuration is similar to that of FIG. 4-A except an optical system 82 replaces system 80. Here a fiber end 88 is moved by an actuator (not shown in FIG. 4-B) and controlled by an alignment control system (not shown in FIG. 4-B) such that a beam from the stacked lasers is coupled into fiber 20 without a separate lens system. Various schemes of fiber-end finishing known to the skilled in the art may be used to enhance the coupling efficiency between the laser and fiber 20.

### CONCLUSION, RAMIFICATIONS, AND SCOPE

Thus it can be seen that I have used stacked diode laser arrays to provide a stack-type tunable laser source.

The laser source has the following advantages:

The ability to extend the wavelength-tunable range by combining two different tunable diode laser arrays.

The ability to improve the laser source reliability by employing two similar diode laser arrays.

Although the description above contains many specificities, these should not be construed as limiting the scope of the invention but as merely providing illustrations of some of the presently preferred embodiments. Numerous modifications, alternations, and variations will be obvious to those skilled in the art.

For example, the diode laser or diode laser array may be of any type, such as distributed Bragg reflector (DBR) laser, DFB laser, light-emitting diode (LED), Fabry-Perot diode laser, or VCSEL. The stacked lasers may consist of lasers of the same type or any combination of the above lasers.

Between a laser diode and an output waveguide in above discussions, optical components such as an isolator and modulator may be inserted. For some applications, a wavelength locker is also required to fine tune the output wavelength. In case where a collimated beam is needed for the isolator, modulator, wavelength locker, etc, lens system 78 of FIG. 4-A may be replaced by two lens systems, one of which collimates beam 94, which passes through the components, and the other directs the beam into fiber 20.

Lastly, a beam from the stacked lasers may also be coupled into a fiber using arrays of mirrors when the beams are not so densely spaced. The mirror-array technique is well known in the filed of optical switch. Take stacked one-dimensional arrays for example. The array stack represents a two-dimensional diode laser array and a virtual two-dimensional beam array. A two-dimensional mirror array, where each mirror serves one diode respectively and exclusively, converts the virtual 2-D array of beams into virtual converging beams. Then a mirror, like mirror 16 of FIG. 1-A, directs each of the virtual converging beams to a fiber, respectively. The two-dimensional mirror array may be replaced by a one-dimensional mirror array, such as in cases where stacked one-dimensional laser arrays are separated by a relatively large distance, assuming that a mirror of the mirror array is able to direct all beams from one laser array.

Therefore the scope of the invention should be determined by the appended claims and their legal equivalents, rather than by the examples given.

What is claimed is:

1. A light source comprising:
1) a plurality of discrete lasers each arranged to emit a beam having a respective wavelength, said lasers each including:
a) a top surface,
b) a bottom surface,
c) a light generating structure disposed between said top and bottom surfaces,
d) a light emitting spot arranged for emitting said beam;
2) bonding means for disposing said lasers such that any one of said lasers is proximate to at least one of the other said lasers; and
3) a coupling element, said coupling element comprising an actuator, said actuator being adjustable for coupling any of said beams to a predetermined optical path, respectively.

2. The light source in claim 1 wherein said optical path is coupled to an optical waveguide.

3. The light source in claim 1 wherein at least one of said lasers includes a laser array.

4. The light source in claim 3 wherein said laser array includes a vertical cavity surface emitting laser (VCSEL) array.

5. The light source in claim 1 wherein said actuator includes a micro-electro-mechanical-system (MEMS) actuator.

6. The light source in claim 1 wherein said coupling element includes at least one lens system and a reflector for directing each of said beams respectively.

7. The light source in claim 1 wherein said lasers are arranged such that said top surfaces of two of said lasers are opposite and proximate.

8. The light source in claim 1, further including a tuning mechanism for tuning said wavelength of at least one of said lasers.

9. The light source in claim 1 wherein said lasers are arranged such that said top surface of one said laser faces said bottom surface of another said laser.

10. The light source in claim 1 wherein said lasers are arranged such that any one of said light emitting spots is proximate to at least one of the other light emitting spots.

11. A light source comprising:
1) a plurality of discrete sub-sources each arranged to emit a beam having a respective spectrum, said sub-sources each including:
a) a top surface,
b) a bottom surface,
c) a light generating structure disposed between said top and bottom surfaces,
d) a light emitting spot arranged for emitting said beam;
2) bonding means for disposing said sub-sources such that any one of said light emitting spots is proximate to at least one of the other light emitting spots; and
3) a coupling element, said coupling element comprising an actuator, said actuator being adjustable for coupling any of said beams to an optical output, respectively.

12. The light source in claim 11 wherein said sub-sources are arranged such that said top surfaces of two of said sub-sources are opposite and proximate.

13. The light source in claim 11, further including a tuning mechanism for tuning said spectrum of at least one of said sub-sources.

14. The light source in claim 11 wherein at least one of said sub-sources is arranged to include a plurality of light emitting spots for emitting a plurality of beams.

15. A method for providing a light source, comprising:
1) disposing a plurality of discrete lasers, said lasers being arranged such that any one of said lasers is proximate to at least one of the other said lasers, said lasers each including:
a) a top surface,
b) a bottom surface,
c) a light generating structure disposed between said top and bottom surfaces,
d) a light emitting spot arranged for emitting a beam at a predetermined wavelength;
2) arranging coupling means between said lasers and an optical output, said coupling means comprising an actuator; and
3) coupling one of said beams to said optical output by adjusting said actuator.

16. The method in claim 15 wherein at least one of said lasers includes a laser array.

17. The method in claim 15 wherein said lasers are arranged such that said top surfaces of two of said lasers are opposite and proximate.

18. The method in claim 15, further including tuning said wavelength of at least one of said lasers.

19. The method in claim 15 wherein said optical output includes a fiber.

20. The method in claim 15 wherein said lasers are arranged such that any one of said light emitting spots is proximate to at least one of the other light emitting spots.
